(19) United States
(12) Patent Application Publication
(10) Pub. No.: US 2009/0071532 A1
(43) Pub. Date: Mar. 19, 2009

(54) Solar cell and fabricating method thereof

(75) Inventors: Chia-Hua Chan, Taoyuan Hsien (TW); Chii-Chang Chen, Taoyuan Hsien (TW); Fu-Yuan Yao, Taoyuan Hsien (TW); Hung-Nan Wu, Taoyuan Hsien (TW); Tai-Kang Shing, Taoyuan Hsien (TW)

Correspondence Address: BIRCH STEWART KOLASCH & BIRCH, PO BOX 747, FALLS CHURCH, VA, 22040-0747, US

(73) Assignee: National Central University

(21) Appl. No.: 12/068,218

(22) Filed: Feb. 4, 2008

(30) Foreign Application Priority Data
Sep. 13, 2007 (TW) 96134166

(51) Int. Cl. H01L 31/04; B05D 1/18

(52) U.S. Cl. 136/252; 427/74

(57) ABSTRACT

A method for fabricating a solar cell device is provided. A container containing a solution with a plurality of nano or micro particles is provided. A solar chip is provided, and the plurality of nano or micro particles in the solution are uniformly coated on a surface of the solar chip by soaking the solar chip in the solution, wherein the plurality of nano or micro particles uniformly coated on the surface of the solar chip are used as an anti-reflective layer. The solar chip is taken out from the solution after being uniformly coated with the plurality of nano or micro particles on a surface thereof.

### BACKGROUND OF THE INVENTION

1. Field of the Invention

The present invention relates to a fabrication method for forming a solar cell device.

2. Description of the Related Art

Continuing population growth and industrial and commercial development has increased the demand for energy sources. Because of the issues of limited natural resources, such as oil, and environmental protection, alternate energy sources have continually been developed. Solar energy produced by solar cells is a great substitute as sunlight is inexhaustible. Therefore, continual advances in solar cell developments may avoid disastrous environmental problems caused by humankind.

Bell Labs in American announced solar cells in 1954. A motive of the research was for supplying an energy source of electric power to remote districts. Efficiency of transforming light into electricity of the solar cell was only 6% at that time. Application of the solar cell was used in the artificial satellite launched in the Soviet Union in 1957 and when the first American landed the moon in 1969. Many materials, such as single crystal silicon, poly-crystal silicon, amorphous silicon, multiple films of poly-crystal silicon and amorphous silicon, etc. The efficiency of transforming light into electricity of the single crystal silicon solar cell is higher than that of other types of solar cells, thus the single crystal silicon solar cell is the most commercially used solar cell product. However, the solar cell has some problems which have not yet to be feasibly solved. The problems are listed as below:

1. The efficiency of transforming solar energy into electric energy of the single crystal silicon solar cell is lower than 15%,

2. The solar cell works under a preferred temperature of lower than 100° C. If the temperature is higher than 100° C., electrical conductivity of the solar cell is substantially raised and thus, weakens semiconductor characteristics. Additionally, structure of the amorphous silicon the solar cell can be destroyed by violent vibration due to heat.

3. Since radiation hardness of the silicon is weak, the solar cell, such as the poly-silicon solar cell, suffers from an aging issue. Therefore, life span of solar cells used in outer space is short. And the efficiency of transforming solar energy into electric energy of the solar cell that has been used for 10 years is decreased to only half that of the original amount.

Among the problems described above, one of the reasons for the low photoelectric transformation efficiency of the solar cell is the low transmittance of sun light. A reason for the low transmittance of sun light is that sun light moving from the environment into a silicon wafer 10, as shown in FIG. 1a, needs to pass through a glass layer 11, an air space 12, an ethylene/vinyl acetate copolymer (EVA) layer 13, and an anti-reflective (AR) coating layer 14. The glass layer 11 is used for protecting the solar cell from external forces and dust. The EVA layer 13 is used as a waterproofing material protecting the solar cell from oxidation due to ambient high temperatures and moisture. The AR coating layer 14 is used for improving the transmittance of sun light to increase the photoelectric transformation efficiency of the solar cell.

Several researchers have reported on a technique of roughing a surface of a material in place of the conventional AR coating layer 14. The technique described above includes performing a plasma etching to a surface of polymethylmethacrylate (PMMA) to forming a roughed surface with an irregular shaped nanorough. FIG. 1b illustrates the differences in topography between of PMMA after and before being etched. The top and the bottom figure respectively illustrate the surface profile of PMMA after and before being etched. The technology improves the transmittance of light by over 3% with a wavelength between 350 nm and 800 nm of PMMA, as shown in FIG. 1c, wherein an upper and a lower curve respectively correspond to PMMA after and before being etched.

The transmittance of the solar cell can be improved by fabricating a thin film 15 with increasing refractive index used as the AR coating layer 14 on the silicon wafer 10, as shown in FIG. 2a. A reflectivity of the solar cell is decreased when light is directed into the thin film 15 and reflecting of light is reduced due to the thin film 15. However, the thin film 15 described above is not easily fabricated. Thus, a nano structure, as shown in FIG. 2b, placing the thin film 15 with increased refractive index is fabricated. In view of the effective refractive index, a device 1 as shown in FIG. 2b is equivalent to a device 1 as shown in FIG. 2a. However, fabricating the device 1 as shown in FIG. 2b is much easier than fabricating the device 1 as shown in FIG. 2a. Thus, a method for fabricating the device 1 as shown in FIG. 2b can be applied to materials not suitable for sputtering a film thereon. While the transmittance of the solar cell can be improved by the method described above, it should be further increased due to the sunlight's wide wavelength range (about 0.3˜1 μm).

### BRIEF SUMMARY OF INVENTION

A detailed description is given in the following embodiments with reference to the accompanying drawings.

The invention provides a solar cell device. An exemplary embodiment of the solar cell device includes a chip having a surface, and a plurality of nano or micro particles formed on the surface of the chip used as an anti-reflective layer.

The invention also provides a method for fabricating the solar cell device. An exemplary embodiment of the method for fabricating the solar cell device includes: providing a container containing a solution with a plurality of nano or micro particles; providing a solar chip, and uniformly coating the plurality of nano or micro particles in the solution on a surface of the solar chip by soaking the solar chip in the solution, wherein the plurality of nano or micro particles uniformly coated on the surface of the solar chip are used as an anti-reflective layer. The solar chip is taken out of the solution after uniform coating of the plurality of nano or micro particles on a surface of the solar chip.

### BRIEF DESCRIPTION OF DRAWINGS

The present invention is more fully understood by reading the subsequent detailed description and examples with references made to the accompanying drawings, wherein:

FIG. 1a is a cross sectional view of a solar cell device.

FIG. 1b is topography of a PMMA film after and before being etched.

FIG. 1c is a figure illustrating transmittance of light as a function of a wavelength between 350 nm and 800 nm of a PMMA film.

FIG. 2a is a cross sectional view of a solar chip.

FIG. 2b is a cross sectional view of a solar chip.

FIG. 3 is a cross sectional view of a solar cell device of an exemplary embodiment according to the invention.

FIG. 4 is a perspective view of a stirring apparatus of an exemplary embodiment according to the invention.

FIG. 5 is a flow chart illustrating an exemplary embodiment of a method for forming a solar cell device according to the invention.

FIG. 6a is topography of a surface of a solar chip with a plurality of nano or micro particles having the diameter of 250 nm uniformly coated thereon.

FIG. 6b is a reflectance spectrum of the solar chip shown in FIG. 6a.

FIG. 7a is a reflectance spectrum of a solar chip with a plurality of nano or micro particles of the same diameter uniformly coated thereon with different raising speeds.

FIG. 7b is a reflectance spectrum of a solar chip with a plurality of nano or micro particles of different diameters uniformly coated thereon.

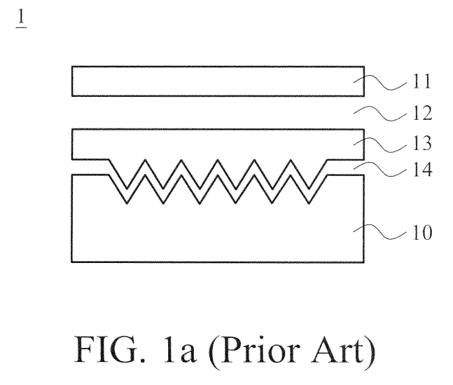

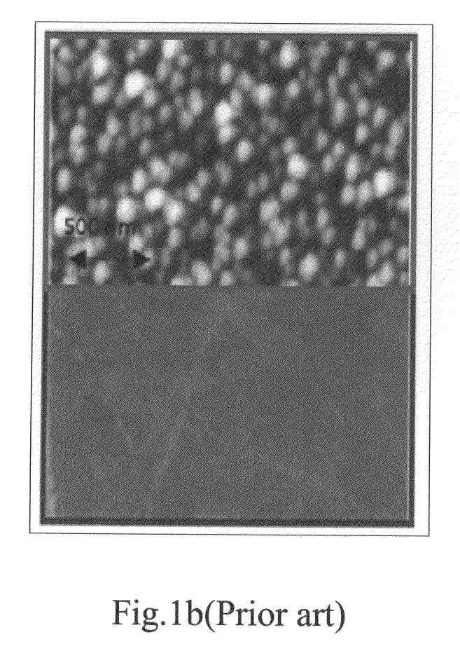

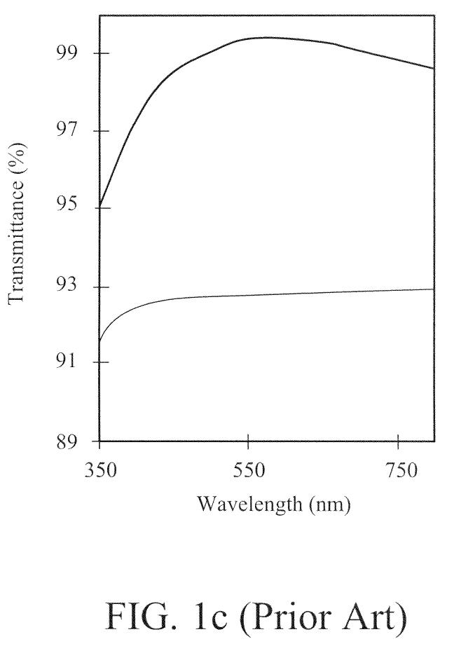

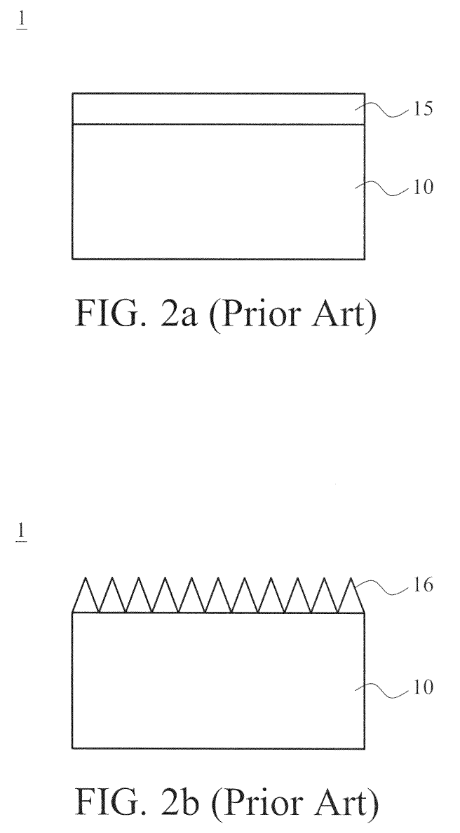

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

Embodiments of the present invention provide a method for forming a solar cell device. References will be made in detail to the present embodiments, examples of which are illustrated in the accompanying drawings. Wherever possible, the same reference numbers are used in the drawings and the descriptions to refer to the same or like parts. In the drawings, the shape and thickness of one embodiment may be exaggerated for clarity and convenience. The descriptions will be directed in particular to elements forming a part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

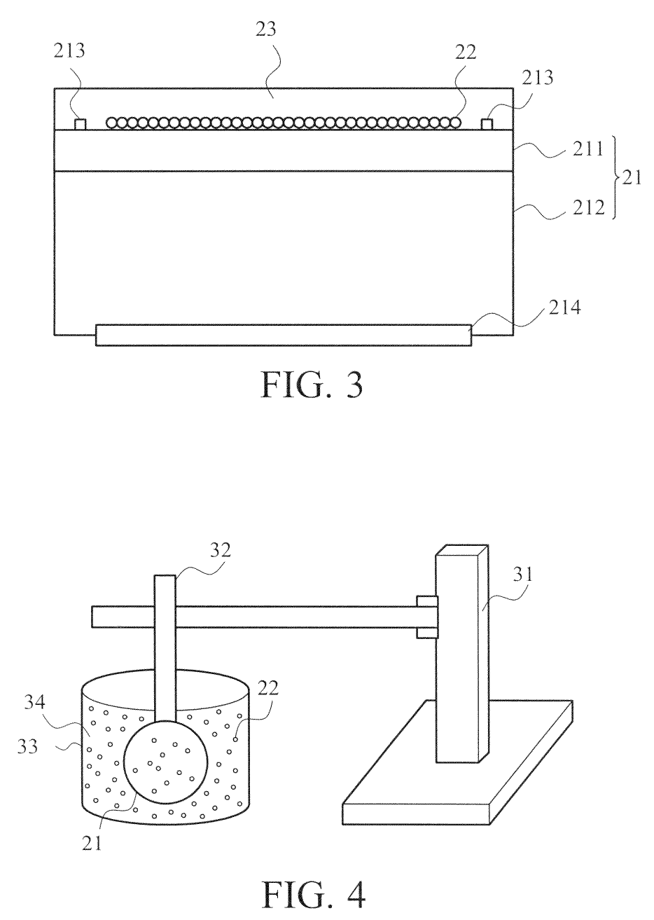

FIG. 3 is a cross-sectional view illustrating a preferred embodiment of a solar cell device including a solar chip 21, a plurality of nano or micro particles 22, and a moisture-protection layer, such as EVA, 23.

The solar chip 21 is an optoelectronic element for transforming solar energy of received sunlight into electric energy. The solar chip 21 includes an N-type layer 211, and a P-type layer 212. A top electrode 213 and a bottom electrode 214 are respectively on a top surface and a bottom surface of the solar chip 21. Composition of and method of forming the solar chip 21, are the same as prior art, and thus not illustrated in detail herein.

The plurality of nano or micro particles 22 may be uniformly coated with a stacked structure, wherein at least one layer is used as an anti-reflective (AR) layer on the top surface of the solar chip 21. The nano or micro particles 22 may be formed by a sol-gel method with materials such as silicon oxide, Polystyrene (PS), or Polymethylmethacrylate (PMMA) etc. The average diameter of the nano or micro particles 22 may be between 90 nm and 750 nm.

The moisture-protection layer 23 may be used for packaging the solar chip 21, the plurality of nano or micro particles 22 and the top electrode 213 on the solar chip 21 for protecting the solar chip 21 from oxidation due to ambient high temperature and moisture. The moisture-protection layer 23 may be transparent glue, or a polymer with good light transmittance and water-proof function.

A stirring apparatus 3, as shown in FIG. 4, may be used for uniformly coating at least one layer of the plurality of nano or micro particles 22 as the AR layer on the top surface of the solar chip 21. The stirring apparatus 3 includes an operation interface 31, a machine arm 32, and a container 33. Parameters related to the uniform coating processes of embodiments include operation of the machine arm 32 controlled by the operation interface 31, temperature, concentration, or a solvent etc. of a solution 34 in the container 33, and the diameter or a material of the nano or micro particles 22. In a preferred embodiment, the parameters of the process may be set as follows:

1. A raising speed of the solar chip 21 may be about 0.5 mm/sec˜5 mm/sec.

2. The concentration of the nano or micro particles 22 of the solution 34 may be about 0.1 wt %˜90 wt %

3. The temperature of the solution 34 may be between 10° C.˜150° C.

4. The solvent of a solution 34 may be ethanol or acetone used for changing a structural arrangement of the solar chip 21 and increasing a processing time for increasing an area and a thickness of the AR layer, wherein the average thickness of the AR layer formed with the nano or micro particles 22 may be about 90 nm˜2250 nm.

5. The nano or micro particles 22 include silicon oxide, polystyrene (PS) or Polymethylmethacrylate (PMMA). In one embodiment, the nano or micro particles 22 is silicon oxide, and the diameter of the nano or micro particles 22 is about 90 nm˜750 nm. The nano or micro particles 22 may have the same diameter and the same material. In other embodiments, the nano or micro particles 22 may have the same diameter and different materials, or have different diameters and the same material.

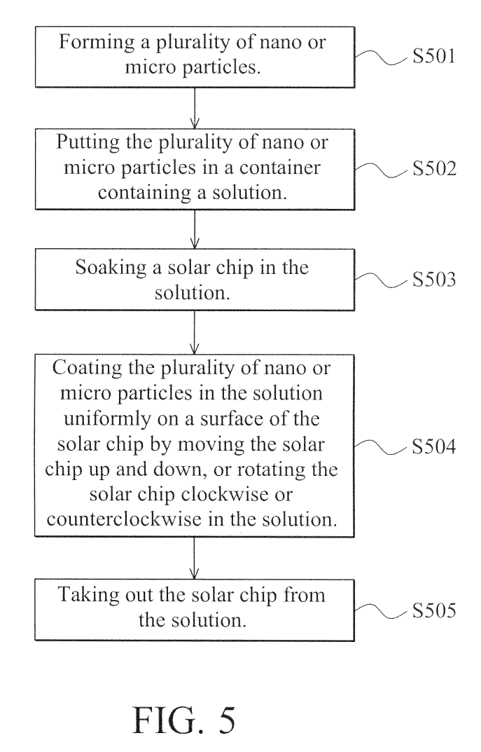

FIG. 5 is a flow chart illustrating an exemplary embodiment of the method for forming the solar cell device according to the invention. The method includes a following steps: a first step S501 of forming the plurality of nano or micro particles 22; a step 502 of putting the plurality of nano or micro particles 22 in the solution 34 in the container 33, wherein the plurality of nano or micro particles 22 are dispersed uniformly in the solution 34; a step 503 of soaking the solar chip 21 in the solution 34; a step S504 of uniformly coating the plurality of nano or micro particles 22 in the solution 34 on the surface of the solar chip 21 by moving the solar chip 21 up and down, or rotating the solar chip 21 clockwise or counterclockwise in the solution 34; and a step S505 of taking out the solar chip 21 from the solution 34. At least one layer of the stacked nano or micro particles 22, such as a silicon oxide layer, acting as the AR layer is formed on the solar chip 21 in place of the AR layer formed by plasma enhanced chemical vapor deposition (PECVD) as used by those of ordinary skill in the art for increasing optoelectronic energy transformation efficiency.

In one embodiment, the nano or micro particles 22 may be formed by the sol-gel method with reactants including organic monomers, inorganic/organic monomer or combinations thereof. The sol-gel method described above includes mixing metal salt, such as silicon oxide, with the solvent, and then progressively forming sol containing colloidal particles therein through hydrolysis and condensation reaction under catalytic of the solvent for a period of time. The method of forming the nano or micro particles 22 further includes steps of filtering, drying, and heating etc. As process and a principle of the sol-gel method are the same as prior art, detailed illustration is not provided herein. In other embodiments, the nano or micro particles 22 may be formed by methods of reversed micelle or hot soap etc.

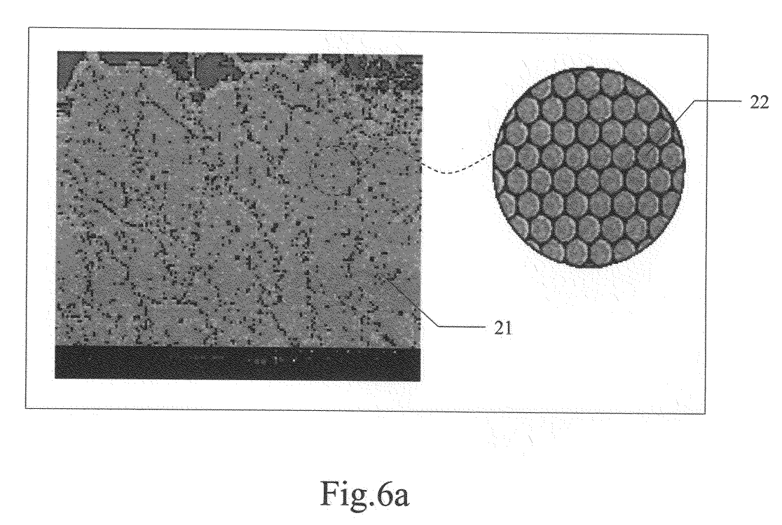

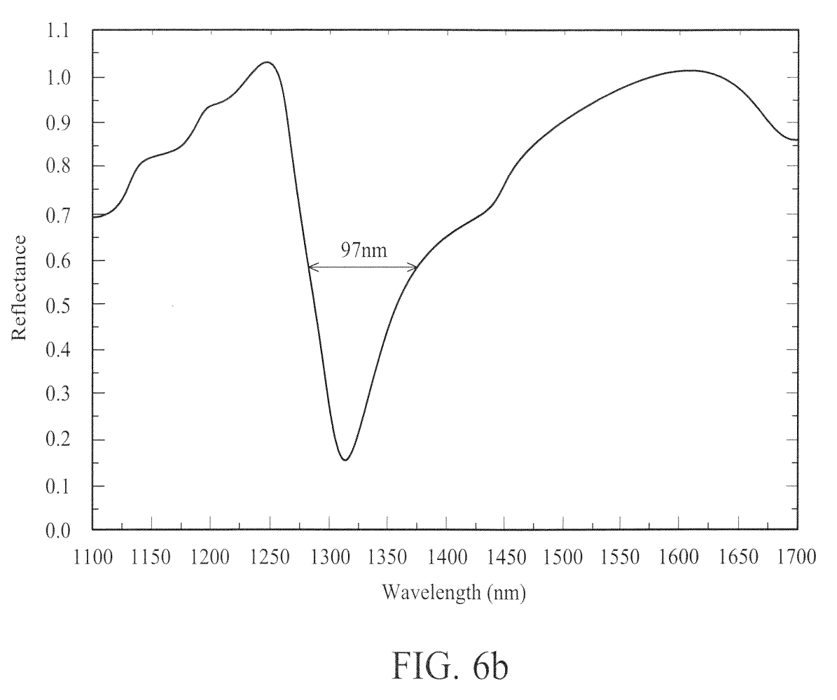

FIG. 6b_is a reflectance spectrum of the solar chip 21 with the plurality of nano or micro particles 22 having the diameter of 250 nm, as shown in FIG. 6a, uniformly coated thereon. The reflectance spectrum as shown in FIG. 6b illustrates that a reflection of light of a wavelength of 1300 nm, compared with light of a wavelength of 1550 nm, is decreased to less than 20%, and has a full-width half-maximum (FWHM) of about 97 nm. Thus, the reflectance of the solar chip 21 may be reduced by uniformly coating the plurality of nano or micro particles 22 on the surface of the solar chip 21 for increasing optoelectronic energy transformation efficiency. The method of uniformly coating the plurality of nano or micro particles 22 described above may be applied to areas of optical communication for separating an optical signal of 1300 nm and that of 1550 nm.

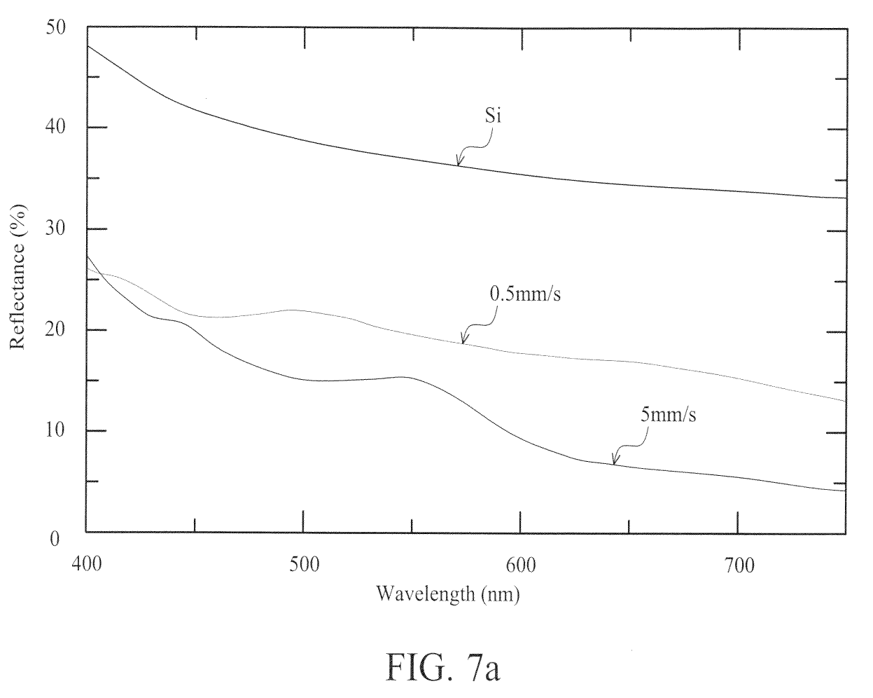

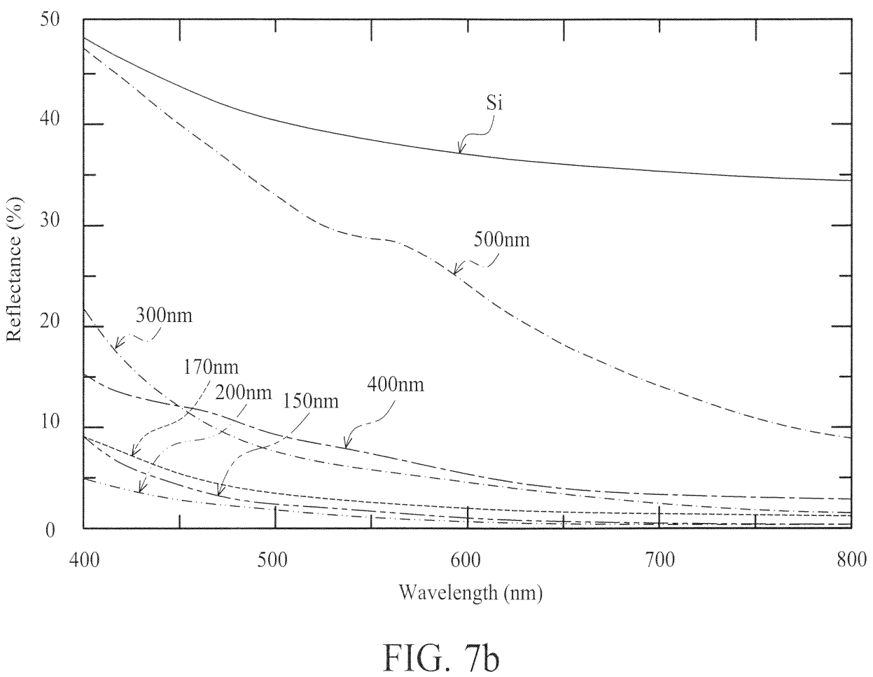

FIG. 7a illustrates plots of reflectance (%) as a function of wavelength (nm) of the solar chips 21 with the plurality of nano or micro particles 22 of the same diameter uniformly coated thereon with different raising speeds. In the wavelength range of 450˜750 nm, the minimum reflectance is 15% for the raising speed of 0.5 mm/s, and the minimum reflectance is about 10% for the raising speed of 5 mm/s. Thus, the optoelectronic energy transformation efficiency of the solar chip 21 is improved.

FIG. 7b illustrates plots of reflectance (%) as a function of wavelength (nm) of 400˜800 nm of the solar chips 21 with the plurality of nano or micro particles 22 of different diameters uniformly coated thereon. The reflectance for the nano or micro particles 22 with a diameter of 150 nm and 200 nm are lower than 1%. Thus, optoelectronic energy transformation efficiency of the solar chip 21 is improved.

The embodiments of the invention have several advantages, for example, a method is provided for forming a plurality of nano or micro particles on a solar cell wafer by dip coating in place of multi-films with more complex methods of increasing refractive index. The formed nano or micro particles on the solar cell wafer has the same result as roughing a surface of the solar cell wafer of reducing reflectance and thus improving optoelectronic energy transformation efficiency of the solar cell wafer. A cost of the method for uniformly coating the plurality of nano or micro particles on a solar cell wafer by dip coating is much lower than the method of rouging the surface of the solar cell wafer.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell device comprising:
a chip having a surface; and
a plurality of nano or micro particles formed on the surface of the chip and used as an anti-reflective layer.

2. The solar cell device as claimed in claim 1, wherein the chip further comprises an N-type layer and a P-type layer.

3. The solar cell device as claimed in claim 1, wherein the chip has a top electrode and a bottom electrode respectively on a top surface and a bottom surface of the chip.

4. The solar cell device as claimed in claim 1, further comprising a moisture-protection layer for packaging the chip and the plurality of nano or micro particles on the surface of the chip.

5. The solar cell device as claimed in claim 4, wherein the moisture-protection layer comprises transparent glue, or a polymer with good light transmittance and water-proof function.

6. The solar cell device as claimed in claim 1, wherein the chip comprises a solar cell.

7. The solar cell device as claimed in claim 1, wherein the nano or micro particles comprise silicon oxide, polystyrene, or polymethylmethacrylate.

8. The solar cell device as claimed in claim 1, wherein the nano or micro particles have an average diameter ranging from 90 nm to 750 nm.

9. The solar cell device as claimed in claim 8, wherein the anti-reflective layer has an average thickness ranging from 90 nm to 2250 nm.

10. A method for fabricating a solar cell device, comprising the steps of:
providing a container containing a solution with a plurality of nano or micro particles;
providing a chip, and uniformly coating the plurality of nano or micro particles in the solution on a surface of the chip by soaking the chip in the solution, wherein the plurality of nano or micro particles are uniformly coated on the surface of the chip as an anti-reflective layer; and
taking out the chip from the solution after uniformly coating the plurality of nano or micro particles on a surface of the chip.

11. The method for fabricating the solar cell device as claimed in claim 10, further comprising forming the plurality of nano or micro particles by sol-gel, reversed micelle, or hot soap.

12. The method for fabricating the solar cell device as claimed in claim 10, wherein the nano or micro particles comprise silicon oxide, polystyrene, or polymethylmethacrylate.

13. The method for fabricating the solar cell device as claimed in claim 10, further comprising moving the chip up and down, or rotating the chip clockwise or counterclockwise in the solution during uniform coating of the plurality of nano or micro particles on the surface of the chip.

14. The method for fabricating the solar cell device as claimed in claim 13, wherein an optoelectronic energy transformation efficiency of the chip is controlled by a raising speed of the solar chip, diameters of the nano or micro particles, a thickness of the anti-reflective layer, a concentration of the nano or micro particles of the of the solution, or a temperature of the solution.

15. The method for fabricating the solar cell device as claimed in claim 14, wherein the raising speed is set between about 0.5 mm/sec and 5 mm/sec, the diameters of the nano or micro particles are between about 90 nm and 750 nm, the average thickness of the anti-reflective layer is between about 90 nm and 2250 nm, the concentration of the nano or micro particles of the solution is between about 0.1 wt % and 90 wt %, and the temperature of the solution is between about 10° C. and 150° C.

16. The method for fabricating the solar cell device as claimed in claim 13, wherein the step of moving the chip up and down, or rotating the chip clockwise or counterclockwise in the solution is operated by a machine arm.

17. The method for fabricating the solar cell device as claimed in claim 10, wherein uniformly coating the plurality of nano or micro particles on the surface of the chip is processed by a stirring apparatus.

18. The method for fabricating the solar cell device as claimed in claim 10, further comprising forming a moisture-protection layer on the chip and the plurality of nano or micro particles on the surface of the chip for packaging the chip and the plurality of nano or micro particles on the surface of the chip.

19. The method for fabricating the solar cell device as claimed in claim 10, wherein the nano or micro particles have the same diameter and the same material, or the nano or micro particles have the same diameter and different materials, or the nano or micro particles have different diameters and different materials.
